(19) United States
(12) Patent Application Publication
(10) Pub. No.: US 2022/0169497 A1
(43) Pub. Date: Jun. 2, 2022

(54) MICROMECHANICAL DEVICE FOR TRANSDUCING ACOUSTIC WAVES IN A PROPAGATION MEDIUM

(71) Applicant: STMICROELECTRONICS S.r.l., Agrate Brianza (IT)

(72) Inventors: Alessandro Stuart SAVOIA, Roma (IT); Domenico GIUSTI, Caponago (IT); Marco FERRERA, Concorezzo (IT); Fabio QUAGLIA, Pizzale (IT)

(73) Assignee: STMICROELECTRONICS S.r.l., Agrate Brianza (IT)

(21) Appl. No.: 17/538,845

(22) Filed: Nov. 30, 2021

(30) Foreign Application Priority Data
Nov. 30, 2020 (IT) 102020000029000

(51) Int. Cl. B81B 3/00; H01L 41/047; H01L 41/083

(52) U.S. Cl. CPC B81B 3/0021; H01L 41/047; B81B 2201/0292; B81B 2201/032; H01L 41/083

(57) ABSTRACT

A micromechanical device for transducing acoustic waves in a propagation medium, comprising: a body; a first electrode structure superimposed to the body and electrically insulated from the body, the first electrode structure and the body defining between them a first buried cavity; and a first piezoelectric element superimposed to the first electrode structure, wherein the body, the first electrode structure, and the buried cavity form a first capacitive ultrasonic transducer, and the first electrode structure and the first piezoelectric element form a first piezoelectric ultrasonic transducer.

### BACKGROUND

### Technical Field

The present disclosure relates to a micromechanical device for transducing acoustic waves in a propagation medium, to a corresponding manufacturing process, and to an apparatus comprising the micromechanical device.

### Description of the Related Art

As is known, ultrasonic transducers are devices that are able to emit and receive acoustic waves (in particular, ultrasound at a frequency comprised between 20 kHz and 100 MHz) in fluid (liquid or gaseous) and/or solid propagation media, by conversion of electromechanical, acoustic, or light energy.

In detail, micro-machined ultrasonic transducers (MUTs) are known manufactured using processes of bulk micromachining and/or surface micromachining of silicon. MUTs comprise membranes capable of vibrating both in the condition of transmission and in the condition of reception of acoustic waves. Currently, vibrational operation of the membranes is based upon piezoelectric effects (piezoelectric MUTs, PMUTs) or electrostatic effects (capacitive MUTs, CMUTs).

The efficiency of electro-acoustic conversion of the energy emitted/received, the frequency-response gain, and the bandwidth are identifying parameters of the MUT. These depend both upon factors proper to the MUTs (such as geometrical structure and materials of the transducers, which determine a mechanical impedance of the MUT) and upon factors proper to the media in which the acoustic waves propagate (such as density of the propagation medium and speed of the sound carried thereby, which determine an acoustic impedance thereof).

Generally, in ultrasound applications, and in particular in low-power applications, high values of electro-acoustic conversion efficiency and bandwidth are necessary to obtain high performance of the MUT, and in particular to obtain high sensitivities (therefore a high signal-to-noise ratio—SNR) and a wide bandwidth (measurement resolution). Optimized performance may be obtained by designing the MUT in such a way that the value of the mechanical impedance of the MUT is close to the value of the acoustic impedance of the propagation medium where the MUT is inserted in the range of operating frequencies mentioned previously. In other words, optimization of the performance of the MUT is obtained in conditions of matching of the mechanical impedance of the MUT with the acoustic impedance of the propagation medium. For instance, the MUT is considered optimized when the value of the mechanical impedance is lower than or equal to the value of the acoustic impedance of the propagation medium in an operating bandwidth of the MUT at −3 dB. In particular, this occurs by selecting appropriately the materials and the structure of the MUT and/or by inserting, at an interface between the membrane of the MUT and the medium of propagation of the acoustic waves, a layer of material capable of modifying the mechanical impedance of the MUT (matching it so as to reduce the difference between impedance values discussed above).

The above problem of impedance matching is particularly felt in the case where the propagation medium is a gaseous medium (e.g., air), given the low value of the acoustic impedance (equal to approximately 400 Rayl), which leads to a high mismatch with the mechanical impedance of the MUT, typically significantly higher (generally ranging between approximately 1 kRayl and approximately 10 MRayl).

In particular, different ultrasound applications in air are known, such as the measurement of distances and the imaging of objects and environments, based upon detection of the echo of the pulse, i.e., upon transmission of the acoustic waves (e.g., of an ultrasound pulse) and upon reception of ultrasonic echoes generated by reflection and diffusion in the environment of the acoustic waves. The spatial distribution and the contained harmonics of the ultrasonic echoes are caused by variations of density in the propagation medium, and are indicative of objects and/or inhomogeneities present therein. Another example of ultrasonic application in air is ultrasonic communication, which implies transmission and reception of a modulated signal over an acoustic channel. In these applications, the bandwidth directly affects the resolution of the measurement (detection of the echo of the pulse) or the transmission/reception of the data (ultrasonic communication).

There is therefore also felt the need, in applications in air, to have MUTs with large bandwidths (e.g., variable in percentage at −3 dB between approximately 3% and approximately 50%). However, transducers micromachined using MEMS (microelectromechanical systems) technology are made of materials (such as silicon, oxides, nitrides, metals) and have typical dimensions of their vibrating membranes (e.g., dimensions ranging from hundreds of nanometres to tens or hundreds of micrometres) that render it difficult to obtain adequately low values of the mechanical impedance. Membranes made of the aforesaid materials and having the aforesaid dimensions show, in conditions of coupling with the air, a resonant behavior with a high quality factor (Q), and therefore an electro-acoustic frequency response with narrow bandwidth both in transmission and in reception.

Known solutions to this problem regard: use of materials with low impedance (e.g., PVDF) or of layers (e.g., made of microporous material such as microfoam) at the interface with the air in order to reduce the mechanical impedance; use of reactive elements (e.g., vibrating diaphragms with small thickness and weight, and therefore with low impedance) or impedance transformers (e.g., elements of a conical shape obtained using the membranes); or introduction of losses in the membranes (e.g., holes in the membranes or in cavity walls that the membranes face). However, these solutions present high manufacturing complexity, as well as presenting complexity of design of the parameters of the MUT. Furthermore, the introduction of losses through dissipative elements or perforated membranes helps to increase the bandwidth, but this occurs at the expense of the efficiency and sensitivity of the MUT. Introduction of reactive elements helps to increase the bandwidth, but there exist limitations in the selection of the materials that can be used in terms of minimum acoustic impedance (for example, the minimum impedance of the microfoams is of the order of 10 kRayl, therefore much greater than the acoustic impedance of air), which lead to a poor effectiveness of impedance matching.

### BRIEF SUMMARY

The present disclosure is directed to providing at least a solution that will overcome the drawbacks as discussed above.

According to the present disclosure, a micromechanical device for transducing acoustic waves in a propagation medium, a corresponding manufacturing process, and an apparatus comprising the micromechanical device are provided.

In at least one embodiment, the micromechanical device includes a body. At least one spacer element coupled to the body. A first electrode structure coupled to the at least one spacer element, the first electrode structure superimposed to the body and overlapping the body, and the first electrode structure electrically insulated from the body. The first electrode structure, the body, and the at least one spacer element delimiting a first buried cavity having a first dimension extending between opposite ones of respective sidewalls of ones of the at least one spacer element. A first piezoelectric element coupled to the first electrode structure, the first piezoelectric element superimposed to and overlapping the first electrode structure, the first piezoelectric element overlapping the first buried cavity, the first piezoelectric element having a second dimension extending between opposite ones of respective sidewalls of the first piezoelectric element, the second dimension being less than the first dimension of the first buried cavity. The body, the first electrode structure and the buried cavity form a first capacitive ultrasonic transducer, and the first electrode structure and the first piezoelectric element form a first piezoelectric ultrasonic transducer.

The first electrode structure may include a first membrane of semiconductor material and a first conductive layer extending between the first membrane and the first piezoelectric element, the first membrane forming a first terminal for the first capacitive ultrasonic transducer and the first conductive layer forming a second terminal for the first piezoelectric ultrasonic transducer.

The micromechanical device may further include a second conductive layer, superimposed to the first piezoelectric element, the first conductive layer and the second conductive layer being in electrical contact with the first piezoelectric element.

### BRIEF DESCRIPTION OF THE SEVERAL VIEWS OF THE DRAWINGS

For a better understanding of the present disclosure, some embodiments thereof are now described, purely by way of non-limiting example, with reference to the attached drawings, wherein:

FIG. 1 shows a cross-section of the present micromechanical device, according to one embodiment;

FIG. 2 is an equivalent circuit diagram of the micromechanical device of FIG. 1, in an operating mode of the same;

FIG. 3 is a graph that illustrates schematically, as a function of a frequency of vibration of a vibrating unit of the micromechanical device of FIG. 1, a pressure spectrum in the operating mode of FIG. 2;

FIG. 4A is a cross-sectional view of the micromechanical device of FIG. 1, in a different operating mode;

FIG. 4B is an equivalent circuit diagram of the present micromechanical device, in the operating mode of FIG. 4A;

FIGS. 5A and 5B are circuit representations that illustrate a tuning impedance of the micromechanical device in the operating mode of FIG. 4A;

FIGS. 6A and 6D are graphs that represent schematically the pressure spectrum as a function of the frequency of vibration of the vibrating element, according to embodiments of the tuning impedance of the micromechanical device in the operating mode of FIG. 4A;

FIGS. 6B and 6C are further graphs that illustrate schematically the pressure spectrum as a function of the vibration frequency of the vibrating element, according to the embodiments of the tuning impedance illustrated in FIGS. 5A and 5B;

FIGS. 7A and 7B illustrate respective steps of a process for manufacturing the micromechanical device of FIG. 1, according to one embodiment;

FIGS. 8A-8D illustrate respective steps of the process for manufacturing the micromechanical device of FIG. 1, according to a different embodiment;

FIGS. 9-11 show, in cross-sectional view, the present micromechanical device according to respective further embodiments;

FIG. 12A is directed to a conventional beamformer;

FIG. 12B is directed to an embodiment of a beamformer;

FIG. 12C is directed to an embodiment of a beamformer;

FIG. 13A is directed to a sub-array of elements, each including one or more of an embodiment of a transducer of the present disclosure;

FIG. 13B is directed to the sub-array of elements, each including the one or more of the embodiment of the transducer of the present disclosure as shown in FIG. 13A;

FIGS. 14A and 14B are directed to graphs with respect to the elements of the sub-array including the one or more of the embodiments of the transducers of the present disclosure as shown in FIGS. 13A and 13B; and

FIG. 15 is directed to an embodiment of an array of sub-arrays including one or more of an embodiment of a transducer of the present disclosure.

### DETAILED DESCRIPTION

Elements in common to the various embodiments of the present micromechanical device, described in what follows, are designated by the same reference numbers.

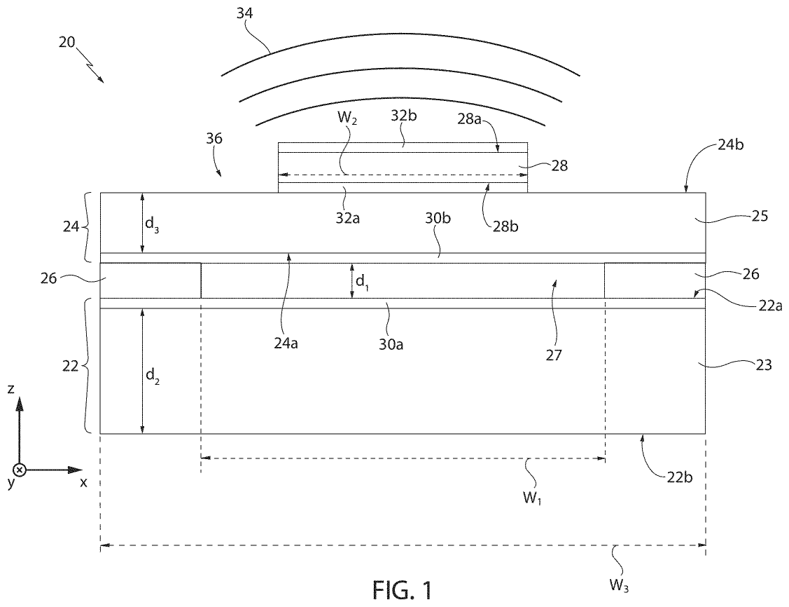

FIG. 1 shows, in a (triaxial) Cartesian reference system of axes X, Y, Z, a micromechanical device 20, which may be a microelectromechanical device.

In detail, in the example of embodiment illustrated, the micromechanical device 20 constitutes a MEMS ultrasonic transducer device, or MUT. In particular, the device 20 is configured to be mounted in an apparatus (not illustrated, such as a notebook, a cellphone, a television set, a motor vehicle, a smartwatch, an ultrasonic probe or a transducer for non-destructive tests) coupled, in use, to a material with low acoustic impedance, as described more fully following herein within the present disclosure.

The device 20, obtained using MEMS (microelectromechanical system) technology, comprises a semiconductor body 22 (made, for example, of silicon), provided with a first surface 22a and a second surface 22b opposite to the first surface 22a. In other words, the first and second surfaces 22a, 22b, respectively, are opposite one another.

The device 20 further comprises a vibrating element, here formed by a membrane 24 of semiconductor material (e.g., silicon) facing the first surface 22a of the semiconductor body 22 and set at a distance from the semiconductor body 22 so as to define a cavity 27 (which is buried and fluidically isolated from an environment external to the device 20) extending between the membrane 24 and the semiconductor body 22. In detail, the membrane 24 is provided with a first surface 24a of its own (facing, at a distance, the first surface 22a of the semiconductor body 22) and a second surface 24b of its own, opposite to the first surface 24a.

The device 20 may comprise one or more spacer elements 26 interposed between the membrane 24 and the semiconductor body 22 so as to delimit the cavity 27 laterally.

The device 20 further comprises a piezoelectric element 28 (or piezoelectric actuator), which is mechanically coupled to the membrane 24 (in detail, extending on the second surface 24b of the membrane 24) and can be actuated to induce vibration of the membrane 24. The piezoelectric element 28 therefore forms, with the membrane 24, a piezoelectric transducer, which may be a piezoelectric ultrasonic transducer. In particular, the piezoelectric element 28 and the membrane 24 are fixed with respect to one another and form a vibrating unit 36. The piezoelectric element 28 is provided with a first surface 28a of its own and a second surface 28b of its own (facing the second surface 24b of the membrane 24), which are opposite to one another. The piezoelectric element 28 comprises one or more layers of piezoelectric material set on top of one another, and at least partially overlies, in a direction parallel to the axis Z, the cavity 27. In greater detail, the piezoelectric element 28 is set, in a direction parallel to the axis Z, at the center with respect to the cavity 27.

As shown in FIG. 1 of the device 20, the cavity 27 includes a dimension W₁ that extends from opposite ones of respective sidewalls of the spacer elements 26 that delimit the cavity 27. The piezoelectric element 28 includes a dimension W₂ that extends from opposite ones of respective sidewalls of the piezoelectric element 28. The dimension W₁ of the cavity 27 is less than the dimension W₂ of the piezoelectric element 28.

For instance, the piezoelectric element 28 extends between a first PZT (Lead Zirconate Titanate) electrode 32a and a second PZT electrode 32b, which are in contact with the second surface 24b of the piezoelectric element 28 and with the first surface 24a of the piezoelectric element 28, respectively. The first and second PZT electrodes 32a and 32b are made of conductive material and for example of metal material (such as Au, Cu, Pt, TiW, Mo, yttrium oxide, Ru) or of semiconductor material with a high concentration of dopant species (e.g., silicon with a concentration of dopant species of an N type higher than 10¹⁸ at/cm³), for biasing the piezoelectric element 28.

As shown in FIG. 1 of the device 20, the respective sidewalls of the piezoelectric element 28 are substantially coplanar and substantially flush with respective sidewalls of the first PZT electrode 32a and respective sidewalls of the second PZT electrode 32b. As shown in FIG. 1, the first and second PZT electrodes 32a, 32b, respectively, have the dimension W₂ similar to the piezoelectric element 28.

In addition, the membrane 24 and the semiconductor body 22 form a capacitive-effect ultrasonic transducer.

In particular, the semiconductor body 22 comprises a substrate 23 and a first conductive layer 30a, which are set on top of the substrate 23 and form the first surface 22a of the semiconductor body 22. As shown in FIG. 1 of the device 20, the semiconductor body 22 has a dimension W₃ that extends between opposite ones of respective sidewalls of the semiconductor body 22. The dimension W₃ of the semiconductor body 22 is greater than the dimension W₁ of the piezoelectric element 28 and is greater than the dimension W₂ of the cavity 27. The respective sidewalls of the semiconductor body 22 is substantially coplanar and substantially flush with respective sidewalls of the spacer elements 26 and respective sidewalls of the membrane 24. In other words, the respective sidewalls of the substrate 23, the first conductive layer 30a, the spacer elements 26, a second conductive layer 30b, and a membrane body 25 are substantially coplanar with each other at the left-hand side and the right-hand side of the device 20 based on the orientation of the device 20 as shown in FIG. 1.

The membrane 24 comprises the membrane body 25 and the second conductive layer 30b, which is set on top of the membrane body 25 and forms the first surface 24a of the membrane 24.

The first and second conductive layers 30a, 30b are made of metal material (such as Au, Cu, Pt, TiW, Mo, yttrium oxide, Al, Ru) or of semiconductor material with high concentration of dopant species (e.g., silicon with a concentration of dopant species of an N type higher than 10¹⁸ at/cm³). The first and second conductive layers 30a, 30b therefore face one another through the cavity 27 and define, with the cavity 27, the plates of a capacitor 30.

In a resting condition of the device 20 (i.e., when no voltages are applied between the PZT electrodes 32a, 32b and between the conductive layers 30a, 30b), the cavity 27 has a depth d₁, measured along the axis Z between the first and second conductive layers 30a, 30b, comprised between 0.05 μm and 100 μm, more in particular between 0.1 μm and 5 μm; for example, it is equal to 1 μm.

According to an embodiment provided by way of example, the thickness d₂ of the semiconductor body 22 (between its surfaces 22a and 22b) is comprised between 10 μm and 710 μm, more in particular between 160 μm and 200 μm, and, for example, is equal to 180 μm, and the thickness d₃ of the membrane 24 (between the surfaces 24a and 24b of the latter) is comprised between 0.5 μm and 50 μm, more in particular between 2 μm and 20 μm, and, for example, is equal to 3 μm.

In particular, the membrane 24 has the same thickness d₃ in every portion thereof (i.e., it has a uniform thickness everywhere).

In use, the device 20 is surrounded by a propagation medium (a fluid, in particular air) propagating in which are acoustic waves 34 generated or detected by the device 20. In detail, the propagation medium 34 is in contact with the second surface 24b of the membrane 24.

When the device 20 is operated in a transmission mode of its own (i.e., it functions as an actuator), the membrane 24 is set in vibration by the piezoelectric element 28 and/or of the capacitor 30, and the vibration of the membrane 24 causes generation and propagation of the acoustic waves 34 in the propagation medium.

When the device 20 is operated in a reception mode of its own (i.e., it functions as sensor), the acoustic waves 34 coming from the propagation medium (e.g., generated by an emitter body external to the device 20), they impinge on the membrane 24 and induce vibration thereof. This induced vibration of the membrane 24 generates a stress in the piezoelectric element 28 and a variation of capacitance in the capacitor 30, enabling detection thereof by the piezoelectric element 28 and/or the capacitor 30, as described more fully hereinafter.

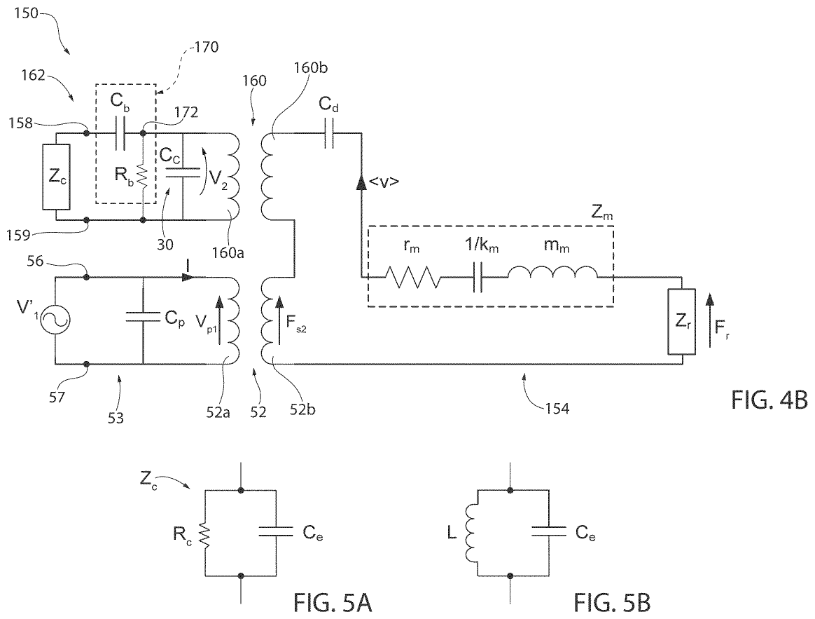

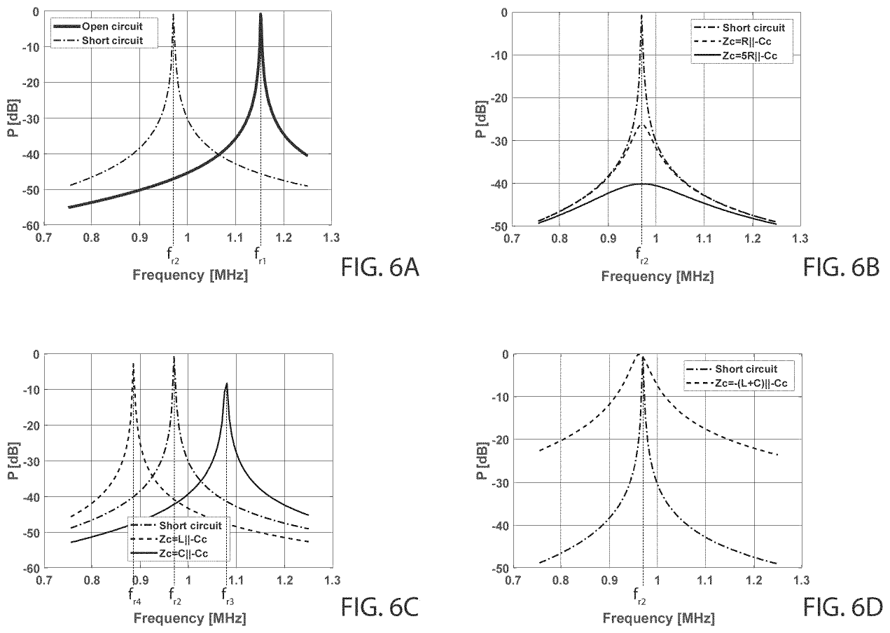

With reference to the transmission mode, a first voltage V₁ (a.c. (alternative current) voltage at a frequency comprised between 30 kHz and 100 MHz, and shown in FIG. 4A) can be applied between the PZT electrodes 32a and 32b, according to different modalities, some of which are described hereinafter. In this way, the piezoelectric element 28 is biased (and therefore actuated) and transfers vibrational energy to the membrane 24, causing deflection and oscillation thereof.

Furthermore, a second voltage V₂ (a d.c. (direct current) voltage, shown in FIG. 4A) can be applied between the conductive layers 30a, 30b, so as to generate, in the capacitor 30, an electric field that extends through the cavity 27. Said electric field generates a force of attraction between the conductive layers 30a and 30b that causes relative approach between the membrane 24 and the semiconductor body 22. When the first voltage V₁ is applied between the PZT electrodes 32a and 32b, application of the second voltage V₂ between the conductive layers 30a, 30b induces a further deflection of the membrane 24 and modifies a mechanical compliance of the latter, thus varying the mechanical impedance of the device 20 (and therefore its frequency response) as described more fully in what follows.

Alternatively, in the transmission mode, the first voltage V₁ may be a d.c. (direct current) voltage and the second voltage V₂ may be an a.c. (alternate current) voltage, in order to set in vibration the membrane 24 by the capacitive effect and to apply a stress on the latter (which causes deflection thereof) due to the piezoelectric effect.

It is thus possible to control the vibrational properties of the membrane 24 by varying the values of the voltages V₁ and V₂. In particular, it is possible to set the membrane 24 in vibration by controlling the piezoelectric element 28 and/or by controlling the capacitor 30.

With reference to the reception mode, the first voltage V₁ and/or the second voltage V₂ are detected in so far as they are indicative of the vibration of the membrane 24 induced by the acoustic waves 34 incident on the latter. Optionally, to improve sensitivity of reception of the acoustic waves 34, it is possible to set the membrane 24 in vibration by one between the piezoelectric element 28 and the capacitor 30 (e.g., by the piezoelectric effect), and simultaneously detect the acoustic waves 34 by the other between the piezoelectric element 28 and the capacitor 30 (e.g., capacitively).

The reception mode and the transmission mode are alternative to one another: the device 20 can therefore operate only in reception, only in transmission, or else both in reception and in transmission, but in periods of time alternating with one another.

The device 20 therefore operates as a piezoelectric/capacitive micromachined ultrasonic transducer (PCMUT).

Various operating modes of the device 20 are described in what follows, by way of example with reference to the transmission mode.

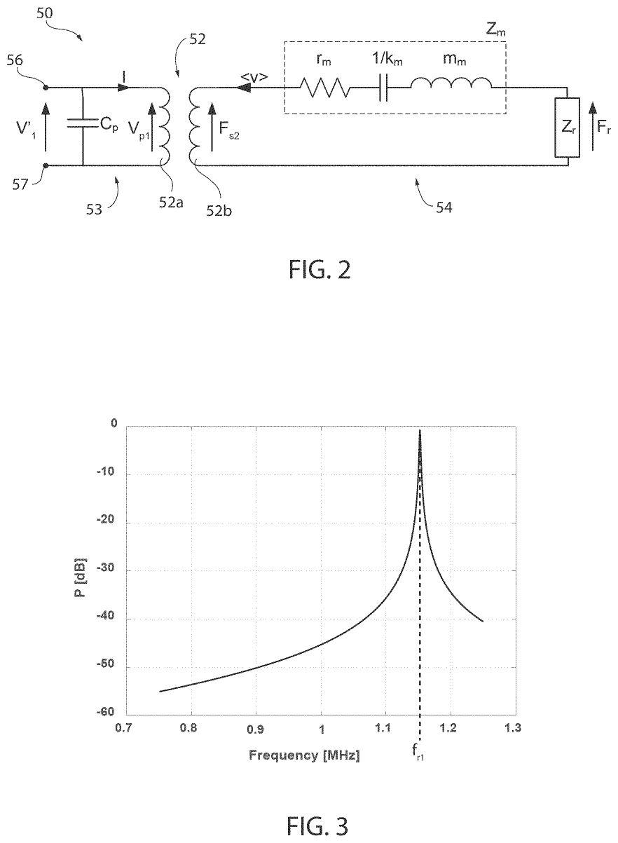

According to a first operating mode of the device 20 (described with reference to FIG. 2), the piezoelectric element 28 is actuated (biased at the first a.c. voltage V₁) in such a way as to cause vibration of the membrane 24, and the capacitor 30 is discharged and is not biased or connected to any circuit. In other words, the capacitor 30 is equivalent to an open circuit.

FIG. 2 shows an equivalent circuit diagram 50 of the device 20 when this operates in the first operating mode. In particular, the circuit diagram 50 is a lumped-element model and models the linearized dynamic small-signal behavior of the device 20 to describe the mechanism of conversion of electrical and mechanical energy thereof.

In FIG. 2, a first electromechanical transformer 52 (with a turn ratio ηₚ of its own) couples together an electrical mesh 53 (associated to a current I and a first primary voltage Vₚ₁, as explained in what follows) and a mechanical mesh 54 (associated to a velocity <v> and to a first secondary-winding force Fₛ₂, as explained in what follows), enabling an exchange of energy between the meshes 53 and 54.

The first electrical mesh 53 comprises a first electrical node 56 and a second electrical node 57, which correspond, respectively, to the PZT electrodes 32b and 32a of FIG. 1. A primary winding 52a of the first transformer 52 extends between the electrical nodes 56 and 57, and a PZT capacitor Cₚ is set in parallel to the primary winding 52a. The PZT capacitor Cₚ corresponds to the capacitance of the piezoelectric element 28, measured between the PZT electrodes 32b and 32a.

The mechanical mesh 54 comprises a secondary winding 52b of the first transformer 52. In parallel to the secondary winding 52b, the mechanical mesh 54 further comprises a series circuit formed by a membrane impedance Zₘ and a radiation impedance Zᵣ.

The membrane impedance Zₘ in turn comprises a membrane resistor rₘ, a membrane capacitor 1/kₘ, and a membrane inductor mₘ, which are connected together in series and form an impedance of the membrane 24. The membrane resistor rₘ, the membrane capacitor 1/kₘ, and the membrane inductor mₘ represent, respectively, the mechanical losses of the membrane 24, the mechanical compliance of the membrane 24, and a mass of the membrane 24.

The radiation impedance Zₑ represents propagation of the acoustic waves 34 in the propagation medium.

As is known, in a transducer of the type considered, in the transmission mode, a first small-signal voltage V₁′, corresponding to the variations of the first voltage V₁ in small-signal regime, is applied between the first and second nodes 56 and 57 and generates the first primary voltage Vₚ₁ across the primary winding 52a of the first transformer 52. The first primary voltage Vₚ₁ is transduced, in the mechanical mesh 54, as a first secondary-winding force Fₛ₂ across the secondary winding 52b of the first transformer 52. On account of the first secondary-winding force Fₛ₂, the vibrating unit 36 transfers to the propagation medium a force, referred to as “radiated force”, Fᵣ, which is identified across the radiation impedance Zᵣ. Instead, in the reception mode, the vibrating unit 36 is subjected to a force applied by the propagation medium, and gives rise to the first small-signal voltage V₁′ existing between the electrical nodes 56 and 57.

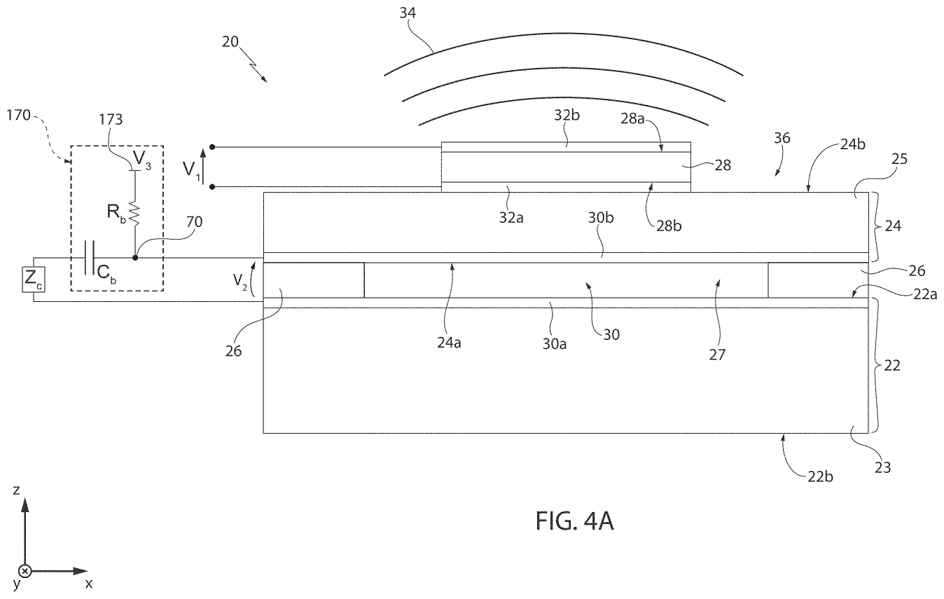

The radiated force Fᵣ is correlated in a known way to the pressure P generated by the vibrating unit 36 on the propagation medium (in the transmission mode) or exerted by the propagation medium on the vibrating unit 36 (in the reception mode), the evolution of this pressure being discussed in what follows with reference to FIG. 3.

FIG. 3 shows the evolution of the pressure P correlated to the radiated force Fᵣ. This pressure P is measured on the second surface 24b of the membrane 24 as a function of the frequency of vibration of the vibrating unit 36 when this operates in the first operating mode.

In particular, the pressure P of the vibrating unit 36 shows a resonant behavior having a peak value at a first resonance frequency fᵣ₁ and having a first quality factor Q₁ correlated to a low value of the bandwidth (for example, lower than 1%).

In a second operating mode of the device 20, discussed with reference to FIG. 4A, the piezoelectric element 28 is actuated by exciting it/driving it with the first voltage V₁, here an a.c. voltage, in such a way as to cause vibration of the membrane 24, and the capacitor 30 of FIG. 1 is biased at the second voltage V₂, here a d.c. voltage.

In particular, the capacitor 30 is electrically connected to a biasing circuit 170 that enables d.c. biasing of the capacitor 30. In addition, the capacitor 30 is electrically connected to a tuning impedance Z_{c}, which makes it possible to regulate and modify the electrostatic effect exerted by the capacitor 30 on the vibrating unit 36 (in particular, on the membrane 24), consequently modifying the mechanical impedance of the device 20 of FIG. 1, as described in detail below.

The biasing circuit 170 and the tuning impedance Z_{c} are electrically connected, in series with one another, to the conductive layers 30a and 30b of FIG. 1. The biasing circuit 170 extends between the tuning impedance Z_{c} and the second conductive layer 30b of FIG. 1. In detail, a first capacitor C_{b} forms, together with a resistor R_{b}, the biasing circuit 170, which is therefore implemented as RC circuit. The first capacitor C_{b} extends between the tuning impedance Z_{c} and the second conductive layer 30b of FIG. 1; a first intermediate node 70 is defined between the first capacitor C_{b} and the second conductive layer 30b of FIG. 1, and the resistor R_{b} extends between the first intermediate node 70 and a power-supply line 173 set at a third voltage V₃, a d.c. voltage. Across the capacitor 30 there is therefore present the second voltage V₂, which is set up on the basis of the division of the third voltage V₃ between the biasing circuit 170, the tuning impedance Z_{c}, and the capacitor 30.

FIG. 4B shows a further equivalent circuit diagram 150 that models the linearized dynamic behavior of the device 20 of FIG. 1 when the device 20 is implemented in the second operating mode (i.e., both capacitively and piezoelectrically) and operates, by way of example, in the transmission mode.

The circuit diagram 150 is similar to the circuit diagram 50 of FIG. 2 and further comprises a second electromechanical transformer 160 (with a turn ratio η_{c} of its own), which couples the mechanical mesh (which is similar to the mechanical mesh 54 and is here identified as mechanical mesh 154) to a second electrical mesh 162.

The second electrical mesh 162 comprises a third electrical node 158 and a fourth electrical node 159, which are electrically connected, respectively, to the conductive layers 30b and 30a of FIG. 1. A primary winding 160a of the second transformer 160 and the first capacitor C_{b} of the biasing circuit 170 are connected to one another in series between the electrical nodes 158 and 159 and define a second intermediate node 172; the capacitor 30 is set in parallel to the primary winding 160a, between the second intermediate node 172 and the fourth node 159. Furthermore, extending in parallel to the capacitor 30 and to the primary winding 160a is the resistor R_{b} of the biasing circuit 170.

The tuning impedance Z_{c} is connected between the electrical nodes 158 and 159.

A secondary winding 160b of the second transformer 160 is comprised in the mechanical mesh 154, and is set in series to the primary winding 52b of the first transformer 52 and to the membrane impedance Zₘ. Furthermore, the mechanical mesh 154 comprises a softening capacitor C_{d} (in particular, with negative capacitance), set in series between the secondary winding 160b of the second transformer 160 and the membrane impedance Zₘ. The softening capacitor C_{d} is indicative of the effect of reduction of the elastic constant in d.c.-biased electrostatic micromechanical structures. This effect, known as “spring softening”, referred to the vibrating unit 36, determines a reduction of the resonance frequency of the membrane 24, which is proportional to the third voltage V₃. The value of the softening capacitor C_{d} is correlated to the capacitance C_{c} of the capacitor 30, and is in particular equal to −C_{c}/η_{c}². Furthermore, the turn ratio η_{c} of the second transformer 160 depends in a directly proportional way upon the third voltage V₃.

With the circuit of FIG. 4A, it is possible, in use, to modify the resonance frequency and/or the quality factor of the pressure of the vibrating unit 36 by acting on the third voltage V₃ and on the tuning impedance Z_{c}. In fact, as described previously, the tuning impedance Z_{c} enables modification of the mechanical impedance of the device 20 (in particular, thanks to the mechanism of energy exchange represented by the second electromechanical transformer 160, which couples the meshes 162 and 154 together). Moreover, the biasing circuit 170 enables application of the second voltage V₂ to the capacitor 30 and therefore modification of the mechanical compliance of the membrane 24, as described previously. Consequently, by acting on these parameters it is possible to control and modify the vibrational behavior of the vibrating unit 36.

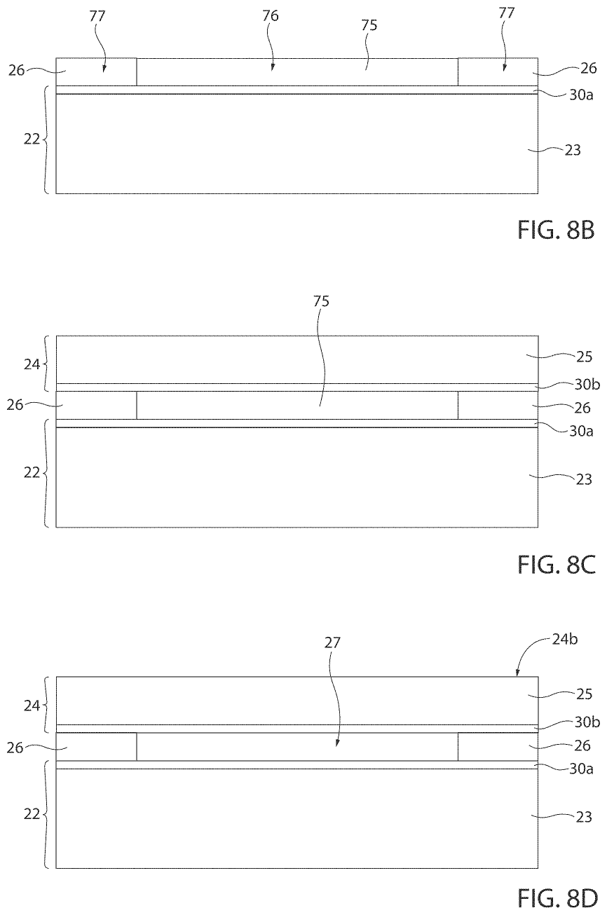

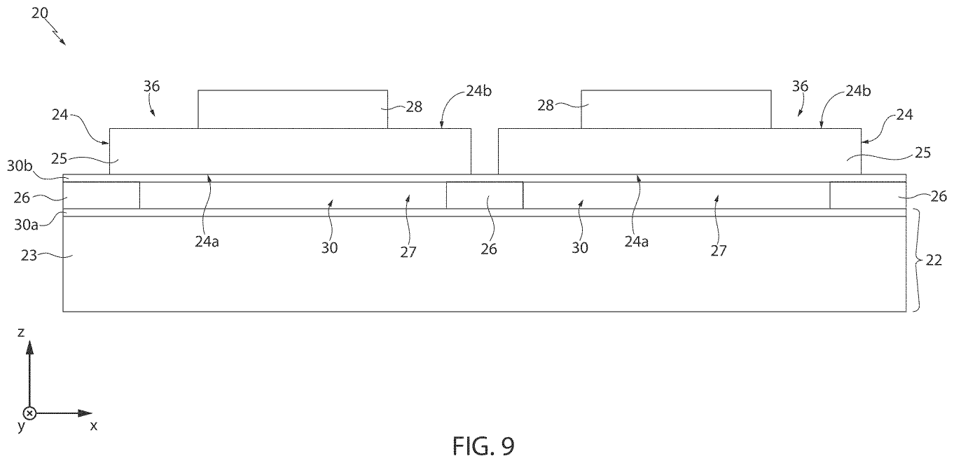

In particular, according to an embodiment, the tuning impedance Z_{c} can be rendered substantially zero (i.e., the nodes 158 and 159 are short-circuited with respect to one another). In this case, as may be seen in FIG. 6A, the behavior of the pressure of the vibrating unit 36 as a function of its own frequency of vibration has a resonance at a second resonance value fᵣ₂ lower than the first resonance value fᵣ₁, and the quality factor is approximately equal to the first quality factor Q₁. In particular, the second resonance value fᵣ₂ is inversely proportional to the third voltage V₃.

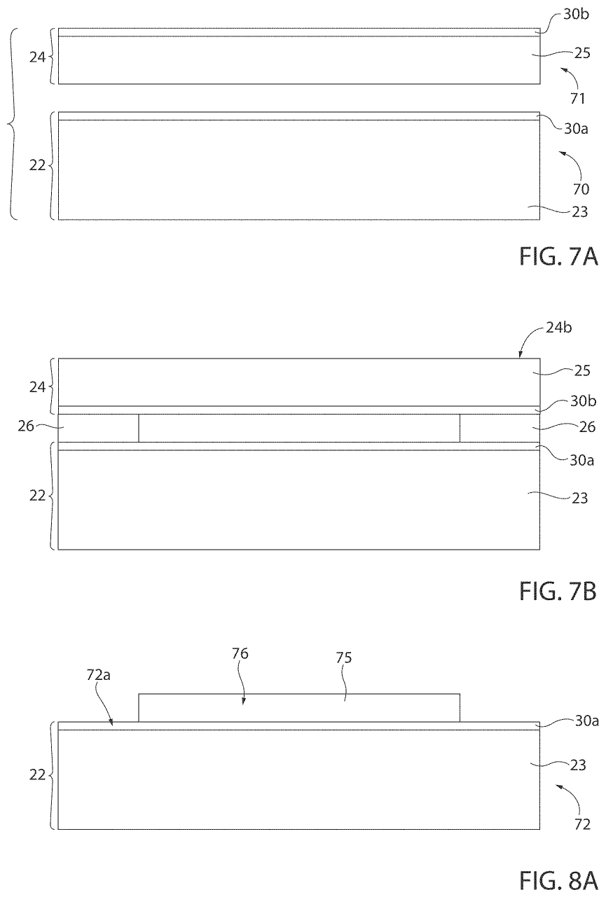

According to a different embodiment of the tuning impedance Z_{c} (discussed with reference to FIG. 5A), the tuning impedance Z_{c} is formed by a tuning resistor R_{c} and a tuning capacitor Cₑ (in particular, with a negative capacitance, and in greater detail a capacitance with a value equal to −C_{c}) in parallel to one another, i.e., Z_{c}=R_{c}∥Cₑ. In this case, as may be seen in FIG. 6B, the behavior of the pressure of the vibrating unit 36 as a function of its own frequency of vibration is of a resonant type with resonance frequency approximately equal to the second resonance value fᵣ₂, and with a value of the quality factor that depends in an inversely proportional way upon the value of the tuning resistor R_{c}. In other words, considering two values R₁ and R₂ of the tuning resistor R_{c}, with R₂<R₁, the respective resonance graphs show a second quality factor Q₂ and a third quality factor Q₃, respectively, with Q₃<Q₂<Q₁. For instance, it is possible to obtain values of the bandwidth of the pressure response of the device 20 comprised between approximately 4% and approximately 20%.

According to a different embodiment of the tuning impedance Z_{c} (discussed with reference to FIG. 5B), the tuning impedance Z_{c} is formed by the tuning capacitor Cₑ and by one between a third capacitor C and a first inductor L, in parallel to one another, i.e., Z_{c}=C∥Cₑ or else Z_{c}=L∥Cₑ (FIG. 5B shows by way of example the case where Z_{c}=L∥Cₑ). In this case, as may be seen in FIG. 6C, the behavior of the pressure of the vibrating unit 36 as a function of its own frequency of vibration has a resonance with a value of the quality factor approximately equal to the first quality factor Q₁, and with values of the resonance frequency different from the second resonance frequency fᵣ₂. In particular, when the tuning impedance Z_{c} comprises the third capacitor C, the respective graph has a third resonance frequency fᵣ₃ higher than the second resonance frequency fᵣ₂ (the third resonance frequency fᵣ₃ is directly proportional to the value of the third capacitor C); when the tuning impedance Z_{c} comprises the inductor L, the respective graph has a fourth resonance frequency fᵣ₄ lower than the second resonance frequency fᵣ₂ (the fourth resonance frequency fᵣ₄ is inversely proportional to the value of the inductor L).

According to a further embodiment of the tuning impedance Z_{c}, the tuning impedance Z_{c} has a value equal to −(L+C)∥Cₑ. In this case, as may be seen in FIG. 6D, the behavior of the pressure of the vibrating unit 36 as a function of its own frequency of vibration has a resonance with resonance frequency approximately equal to the second resonance frequency fᵣ₂, with an attenuation smaller than in the cases previously discussed (therefore at higher pressure values and with a higher sensitivity) and with a fourth quality factor Q₄ lower than the first quality factor Q₁. In particular, the fourth quality factor Q₄ is directly proportional to the values of the third capacitor C and of the inductor L. Consequently, the possibility of reducing the quality factor determines a respective increase (e.g., comprised between approximately 0.5% and approximately 4%) of the bandwidth of the pressure response of the device 20.

The device 20 of FIG. 1 is obtained with the manufacturing process described in what follows.

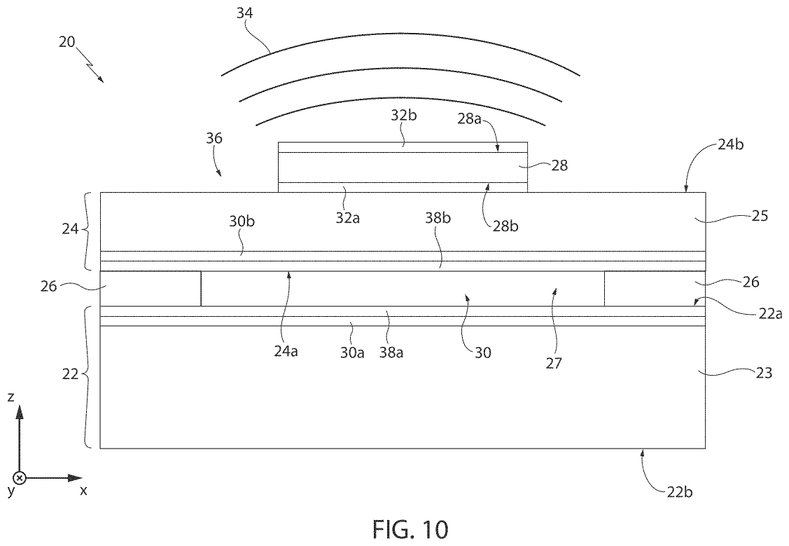

With reference to FIGS. 7A-7B, the manufacturing process according to one embodiment is described.

In FIG. 7A, the semiconductor body 22 (comprising the substrate 23 and the first conductive layer 30a) is formed starting from a first wafer 70 of semiconductor material. For instance, the first conductive layer 30a is formed by implanting dopant species or depositing one or more metal layers on the substrate 23. In addition, the membrane 24 (comprising the second conductive layer 30b) is formed starting from a second wafer 71 of semiconductor material. For instance, the second conductive layer 30b is formed by implanting dopant species or depositing one or more metal and dielectric layers (e.g., passivation layers) on the membrane body 25.

In FIG. 7B, the semiconductor body 22 and the membrane 24 are bonded together by interposition of spacer regions (which are to form the spacer elements 26) and bonding layers (not illustrated) in such a way that the first and second conductive layers 30a, 30b face one another. For instance, a bonding can be carried out of a direct-bonding type (such as Si—Si, Si—SiOx, SiOx—SiOx), a metal type, a eutectic type, an adhesive type, or a glass-frit type.

Next, in a way not illustrated, a step of grinding of the membrane body 25 is carried out to reduce the thickness thereof (so that the membrane 24 will have the thickness d₃ described previously), and the piezoelectric element 28 and the PZT electrodes 32a and 32b are formed on the surface 24b of the membrane 24 in order to obtain the device 20 of FIG. 1.

Alternatively, the piezoelectric element 28 and its own PZT electrodes 32a and 32b are formed on the second wafer 71 before carrying out the bonding described previously.

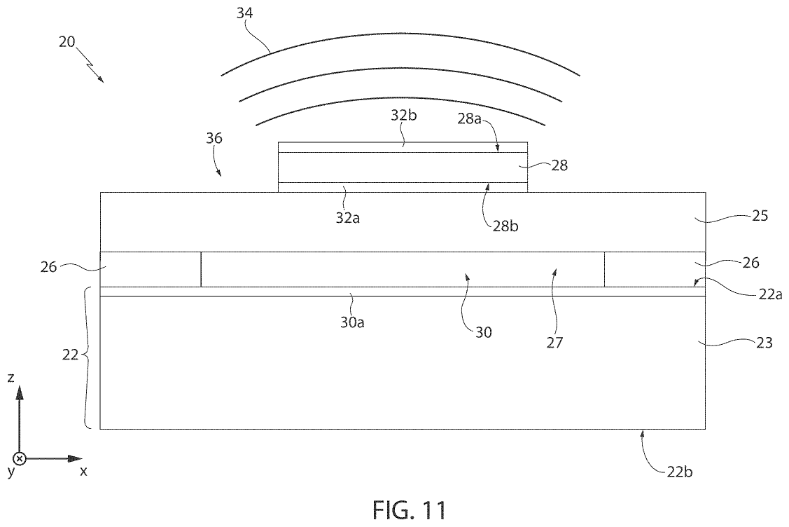

With reference to FIGS. 8A-8D, the manufacturing process according to a different embodiment is described.

In FIG. 8A, in a way similar to what has been described above in regard to FIG. 7A, the semiconductor body 22 is formed starting from a third wafer 72 of semiconductor material having a first surface 72a. A sacrificial region 75 (e.g., of SiO₂) is formed (for example, by thermal oxidation or by deposition of oxide) on the first surface 72a of the third wafer 72, at a first region 76 of the latter. The first region 76 is to face the cavity 27.

In FIG. 8B, the spacer element 26 is formed on the first surface 72a of the third wafer 72, at second regions 77 of the latter, which are complementary to the first region 76.

In FIG. 8C, the membrane 24 (comprising the membrane body 25 and the second conductive layer 30b) is formed on the spacer element 26 and on the sacrificial region 75, for example by epitaxial growth of silicon.

In FIG. 8D, the sacrificial region 75 is removed by etching, for example by wet chemical etching, to form the cavity 27. In particular, one or more holes are formed through the membrane 24 starting from the second surface 24b of the membrane 24 until the sacrificial region 75 is reached, thus enabling the agent used for etching to reach the sacrificial region 75.

Furthermore, the piezoelectric element 28 and the PZT electrodes 32a and 32b are formed on the surface 24b of the membrane 24 in the way described above in order to obtain the device 20 of FIG. 1.

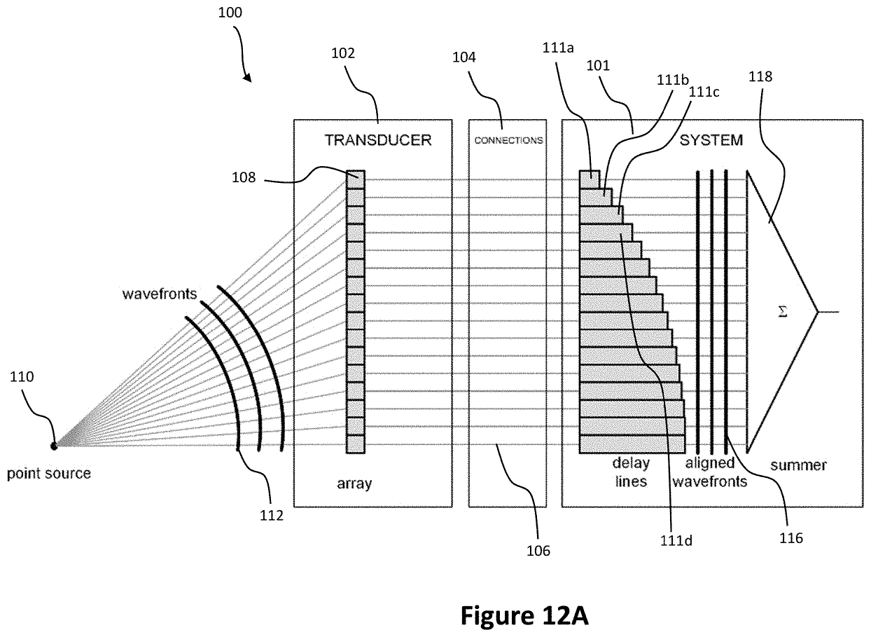

FIG. 9 shows the device 20 according to a different embodiment. In particular, in FIG. 8, the device 20 is similar to the one illustrated in FIG. 1, but comprises a plurality of piezoelectric elements 28 (each with respective PZT electrodes 32a and 32b, and not illustrated in FIG. 8), a respective plurality of cavities 27, and a respective plurality of membranes 24. The membranes 24 share a same second conductive layer 30b (e.g., a metal layer), but comprise respective membrane bodies 25, spaced apart from one another. Each membrane 24 is set on top of a respective cavity 27 and forms, with the latter and with the semiconductor body 22, a respective capacitor 30. The capacitors 30 are electrically connected to one another in parallel since they share the conductive layers 30a and 30b. The cavities 27 are pneumatically isolated from one another and with respect to the environment external to the device 20. In detail, the plurality of piezoelectric elements 28, cavities 27, and membranes 24 are arranged with respect to one another so as to replicate a number of times the structure illustrated in FIG. 1. In other words, the device 20 of FIG. 1 comprises just one cell for transducing acoustic waves, whereas the device 20 of FIG. 9 comprises a plurality of cells for transducing acoustic waves, independent from one another and set alongside one another on the semiconductor body 22 (e.g., in a direction parallel to the axis X and/or the axis Y).

As an alternative to what has been illustrated, the device 20 comprises a plurality of first conductive layers 30a electrically decoupled from one another and a plurality of second conductive layers 30b, electrically decoupled from one another. In this case, the capacitors 30 are electrically decoupled from one another.

Even though in FIG. 9 just two cavities 27, two membranes 24, and two piezoelectric elements 28, are represented by way of example, it is to be understood that said number may vary and may be larger.

The present device affords numerous advantages.

In particular, the device 20 operates as an ultrasonic transducer with mechanical properties variable as a function of some parameters (the first voltage V₁ applied between the PZT electrodes 32a and 32b, the third voltage V₃ applied to the biasing circuit 170, and the tuning impedance Z_{c}). In fact, by applying the first voltage V₁ between the PZT electrodes 32a and 32b it is possible to induce the membrane 24 to vibrate, and by electrically charging the capacitor 30 (i.e., applying the third voltage V₃ to the biasing circuit 170 and designing the tuning impedance Z_{c}) it is possible to vary the equivalent mechanical properties of the device 20.

Moreover, the possibility of varying the mechanical properties of the device 20 by acting only on the voltages V₁ and V₃ makes it possible to obtain in a very simple way high versatility, adaptability, and performance. This is important in applications such as formation and control (deflection and focusing) of acoustic beams, for example by “array beamforming” techniques.

The device 20 may also be used in applications that require an operation with small bandwidth of the device 20, such as for use in air. In this case, in fact, functionality of the device 20 can be optimized by acting on the parameters mentioned previously, by matching of the resonance frequency and of the quality factor and by reduction of the equivalent mechanical impedance of the vibrating unit 36.

As an alternative to what has been described previously, it is possible to carry out simultaneously the operations of data transmission and reception when the piezoelectric element 28 is used only for generation of acoustic waves 34 (for example, for transmission of signals) and the capacitor 20 is used only to detect the acoustic waves 34 coming from the propagation medium (for example, for the reception of signals), or vice versa.

It is moreover possible to modulate the signals transmitted, using, for instance, the piezoelectric element 28 to generate a carrier signal and the capacitor 20 to generate a modulation signal to be superimposed on the carrier signal (or vice versa).

Finally, it is clear that modifications and variations may be made to the device described and illustrated herein, without thereby departing from the scope of the disclosure.

In particular, regulation of the properties of the membrane 24 performed by the tuning impedance Z_{c} may even not be obtained only by discrete circuit elements. In this case, the tuning impedance Z_{c} may be replaced by a circuit network of a passive or active type (and therefore comprise elements such as operational amplifiers, etc.).

Furthermore, as an alternative to what has been described previously, in the reception mode one between the piezoelectric element 28 and the capacitor 30 can be implemented as described previously to modify the mechanical impedance of the device 20, while the detection of the vibrations of the membrane 24 induced by the incident acoustic waves 34 may be obtained according to known pressure-detection techniques. For instance, it is possible to exploit a further piezoelectric element (not illustrated, similar to the piezoelectric element 28 and designed to generate a signal indicative of the vibration of the membrane 24 to which it is mechanically coupled), or else one or more pressure sensors (not illustrated and of a known type), mechanically coupled to the membrane 24. Consequently, the device 20 is used so as to modify the mechanical impedance thereof (by control of the piezoelectric element 28 or of the capacitor 30), while detection of the vibration of the membrane 24 is carried out by an element not comprised in the device 20, but coupled to the latter.

Optionally, as shown in FIG. 10, the semiconductor body 22 further comprises a first insulating layer 38a (e.g., made of silicon oxide or silicon nitride) set on top of the first conductive layer 30a and defining the first surface 22a of the semiconductor body 22; and the membrane 24 further comprises a second insulating layer 38b (e.g., made of silicon oxide or silicon nitride) set on top of the second conductive layer 30b and defining the first surface 24a of the membrane 24.

The first and second insulating layers 38a and 38b face one another through the cavity 27 and guarantee mutual electrical insulation of the first and second conductive layers 38a and 38b even in the case of direct physical contact of the first surface 24a of the membrane 24 with the first surface 22a of the semiconductor body 22. For instance, said contact can be caused by application of external forces acting on the membrane 24 in a direction parallel to the axis Z, or of oscillations of the membrane 24 itself, such as to generate a deflection of the latter sufficiently extensive as to bring it into contact with the semiconductor body 22.

Optionally, just one between the first insulating layer 38a and the second insulating layer 38b is present. Also in this case, it is possible to guarantee mutual electrical insulation of the first and second conductive layers 38a and 38b in the case of direct physical contact of the membrane 24 with the semiconductor body 22.

Furthermore, according to a different embodiment of the device 20 illustrated in FIG. 11, the second conductive layer 30b and the second insulating layer 38b are absent, and the membrane body 25 is made of insulating material (e.g., silicon oxide or silicon nitride). In this case, the first PZT electrode 32a forms an electrode region shared between the capacitor 30 and the piezoelectric transducer 36. In practice, the capacitor 30 is formed by the first PZT electrode 32a, the membrane body 25, and the first conductive layer 30a; and the piezoelectric ultrasonic transducer is formed by the first PZT electrode 32a, the piezoelectric element 28, and the second PZT electrode 32b.

The embodiments of the transducers 36 of the present disclosure as discussed herein can be used to implement a phase-shift micro-beamformer by exploiting the nonlinearity of the electrostatic transduction.

In a traditional or conventional delay-and-sum beamformer 100, transmit and receive signals are processed by a dedicated ultrasound scanner system 101. A transducer array 102 is interfaced using one connection 106 of an array of connections 104 per array element 108 of the transducer array 102. The number of connections 106 between the transducer array 102 and the dedicated ultrasound scanner system 101 is at least equal to the total number of array elements 108. In some ultrasound scanner systems, there may be hundreds or thousands of connections that are coupled between the transducer and the ultrasound scanner system. These connections may be physical cables with individual ports that must be coupled between the transducer and receiver. Decreasing the number of connections 106 can be useful to reduce the complexity and cost of the interfacing, especially in the case of large element count arrays, such as, for example, 2D arrays for volumetric beam steering.

In transmit, the beamforming system generates delayed electrical excitation signals and applies them to the transducer array elements, which converts them into delayed acoustic waves that proagate and interfere (coherently sum) in the medium (e.g. human tissue). The medium reflects and back-scatters these acoustic waves (echoes). In receive, these echoes are converted by the transducer array elements into electrical signals that are delayed and summed by the beamforming system.

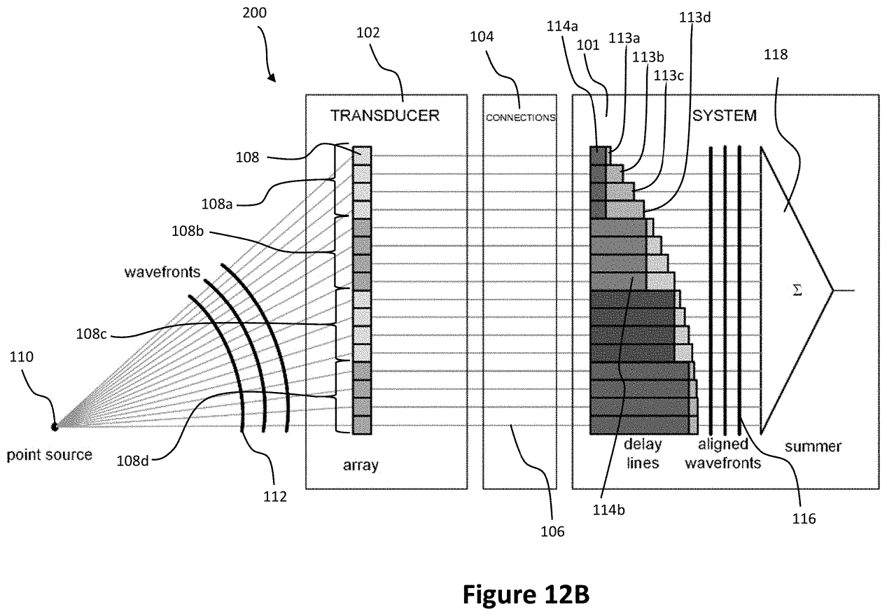

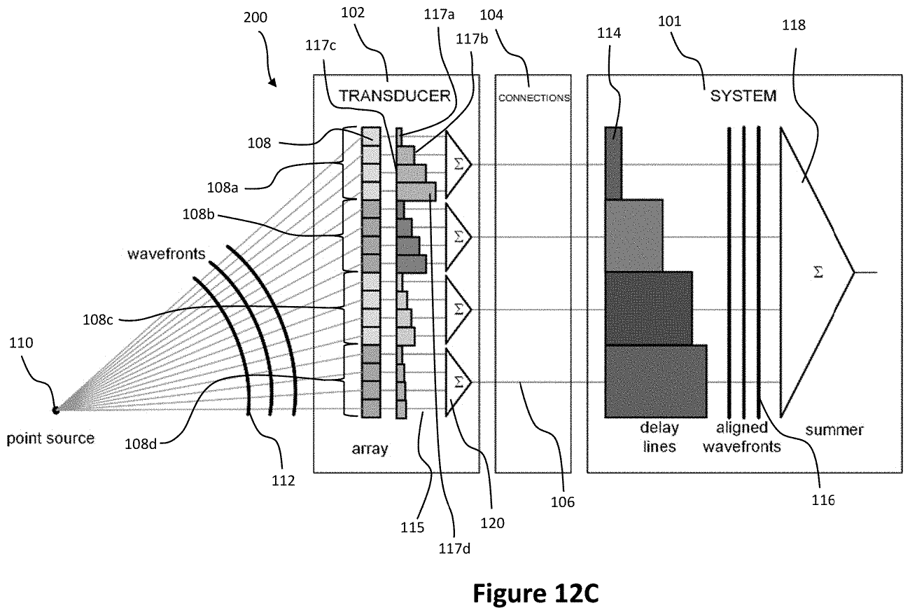

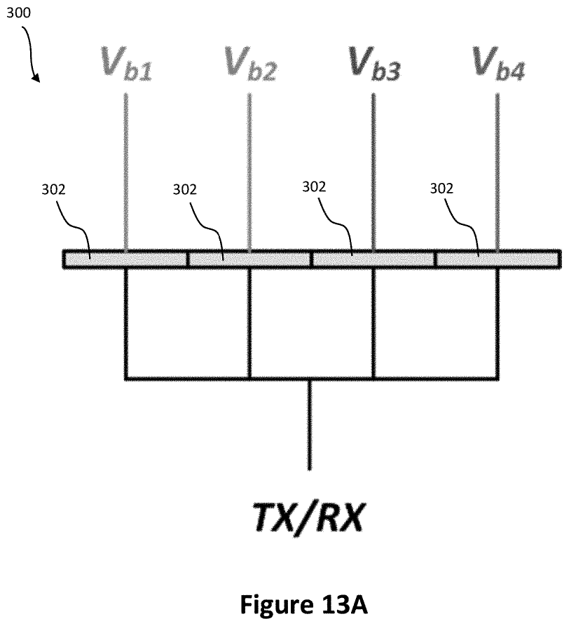

One way to reduce the number of connections 106 is known as “micro-beamforming.” This method includes providing the transducer array 102 with the capability of performing delay-and-sum on small groups of the array elements 108. FIG. 12A gives a schematic description of the classical delay-and-sum beamforming method operating in a transceiver mode on the system side (as it is typically implemented in existing ultrasound scanning systems).

In FIG. 12A, a point source 110 emits curved wavefronts 112, which propagate from the point source 110 and are detected by an N-element, for example N=16, array aperture, such as the transducer array 102. The N acoustic signals are fed to the system 101 through N connections 106, for example cables. The system 101 performs the delay-and-sum of the signals by applying N delays 111a, 111b, 111c, 111d, etc. to conveniently re-align the wavefronts 116 and by summing the aligned signals 116 utilizing the summer 118. Each delay 111 is somewhat different from adjacent ones of the delay, which are illustrated by different sizes of the rectangular bars 111. Each bar representing each delay 111 is a fine or specific delay for each connection 106 or array element 108.

The same result can be achieved by grouping array elements 108 of the transducer that have similar delay values 111, which is typically the case for adjacent elements 108. FIG. 12B is an intermediate scheme showing a delay-and-sum beamformer 200 where adjacent ones of the N array elements 108 are grouped in sub-arrays of elements 108a, 108b, 108c, 108d of M elements, for example, as shown in FIG. 12B, M=4.

For each group, the associated delays 111 can be represented as the sum of one common delay, such as a first coarse delay 114a that is applied to the top four array elements 108, and M individual “micro” delays, such as the “micro” delays 113a, 113b, 113c, 113d for the top four array elements 108. A second common coarse delay 114b is applied to the next four array elements 108 and is summed with the next four micro delays of the next four array elements 108. Each coarse delay is an approximation of the fine delays 111 of the respective array elements 108. Each delay of each group is the addition of the smaller lighter rectangular bars that represent the individual micro delays and the square darker bars represent the collective or common coarse delay 114a. A difference between each fine delay 111 and the first coarse delay 114a is the micro delays 113a, 113b, 113c, 113d, which is illustrated with the lighter right-most rectangles.

FIG. 12C is an alternative embodiment that applies the micro or common delays on the transducer side as opposed to the ultrasound scanner system side. In one embodiment of the micro-beamforming system 200, the task of applying the “micro” delays is carried out by dedicated processing units 120 placed very close to or within the transducer 102. The micro-beamforming units 120 delay and sum M signals 115 and feed the resulting signals along the connection 106 to the system 101, using only one connection 106 per unit 108a, 108b, 108c, 108d. The coarse delays 114 are applied on the system side to re-align the wavefronts 116. The micro delay equivalents 117a, 117b, 117c, and 117d are applied on the transducer side and the coarse delays 114 are applied on the system side. The system then sums the outputs of from the delays 114, achieving the same result as the conventional beamforming approach as shown in FIG. 12A. The number of connections 106 is reduced from M to N/M as shown in FIG. 12C.

Integrating the delay and summation into the transducer side in the case of the transmission of the micro-beamforming system 200 can be challenging due to the high voltage characteristic of the transmit signals. Therefore, most of the solutions include integrating receive-only microbeamformer ASICS inside a probe, physically close to the transducer. On the other hand, using the piezo and electrostatic transducers of the present disclosure in the transducer array, the system can simplify the number of connections between the transducer and the ultrasound scanner system without the same ASICS needed in the probe as better detailed below. For example, this can benefit beamforming systems that are large, such as with thousands of connections or channels that are otherwise impractical to implement. For example, these large systems exist in medical ultrasound imaging arrays.

The delays 117a, 117b, 117c, 117d correspond to the difference between the fine delays 111 and the course delays 114 in FIG. 12B, and are the same as or otherwise represent the micro delays 113a, 113b, 113c, 113d in FIG. 12B. The delays 117a, 117b, 117c, 117d address the delay not addressed by the larger, coarse delay 114a associated with the adjacent elements, such as the top group of 4 elements in this example. The ultrasound scanner system is simplified in that a single connection is associated with the delay 114a, corresponding to the transducer side summation of the 4 elements after applying the difference between the delay 114a and the fine delay from the FIG. 12B example. Said differently, the delays 117a, 117b, 117c, 117d represent the differences or micro delays 113a, 113b, 113c, 113d between the fine delays 111 and the coarse delay 114 in FIG. 12B.

Depending on the implementation, a micro-beamformer can apply time-delays of phase-delays. In the case of narrowband or continuous wave (monochromatic) signals, the two approaches as discussed above provide exactly the same results, while for broadband signals, the phase-delay implementation can be less accurate. However, the phase-delay implementation is easier to realize and provides good results for broadband signals characterized by a fractional bandwidth in the order of 80%.

A phase-shift micro-beamformer based on the electrostatic nonlinearity of capacitive micro-machined ultrasonic transducers (CMUTs), exploits the spring-softening effect, previously described, to control the phase of the electro-acoustic response by changing the bias voltage of the CMUT. This allows implementing a micro-beamformer operating in both transmit and receive operation with a significantly reduced complexity of the control electronic circuitry, which potentially consists of M voltage generators (not shown) for each micro-beamforming unit, and simple decoupling and filtering networks (implementable using passive components). However, it presents the disadvantage that, in a CMUT, changing the bias voltage has an effect not only on the phase, but also on the magnitude of the electro-acoustic response. Therefore, the approach may include additional attenuator blocks (one per array element), which equalize the magnitude of the response of elements biased with different voltages, which reduces the performance in terms of transmit and receive sensitivity and introduces the need of additional hardware components and control signals.

The present disclosure is directed to a system that includes both a PMUT and a CMUT in the transducer element where the CMUT bias voltage can be utilized to manage the phase and a PMUT excitation voltage can be utilized to manage the amplitude. Integrating the CMUT and PMUT of the present disclosure can minimize the dedicated electronics utilized in current systems, such as in the probe.

In traditional CMUT systems, a change in the bias voltage affects both the phase and amplitude of the response. By utilizing the CMUT and PMUT of the present disclosure, the system can manage individually the phase and amplitude. The phase is controlled by the bias voltage of the CMUT and the amplitude is controlled by the excitation voltage of the PMUT.

A CMUT and PMUT transducer arrangement can be included in the system of FIG. 12C, that includes the elements 108a, 108b, 108c, 108d or groups of piezoelectric and electrostatic elements that are configured to receive the wavefronts from the point source 110. Each transducer element 108 may be one of the micro-electromechanical transducer devices, such as device 20 of FIG. 1. The piezo and electrostatic transducer devices of the present disclosure integrated into the transducer side of the micro-beamforming system 200 can simplify the overall system by reducing the number of connections or cables 106 and can simplify the system side to only handle the coarser delays 114.

In addition, moving the delay and summation to the transducer side allows for phase shift management by acting on the bias voltage applied to the electrostatic elements and the excitation voltage of the piezo elements of the present disclosure. Piezo ultrasound transducers are linear, while the electrostatic transducers are non-linear. Utilizing a piezo micro-machined ultrasonic transducers (PMUT) with a linear response and a CMUT with a non-linear response in a single transducer element allows for control of the frequency response. With each transducer element having two ports, the electrostatic port and the piezoelectric port, amplitude and phase modulation can be achieved by controlling the different voltages of these ports. For example, the electrostatic port, CMUT allows for control of the phase of the response and the PMUT allows for control of the amplitude of the response. One advantage is that the phase and amplitude control are decoupled using the devices of the present disclosure.

The problems that arise from controlling the CMUT, impacting the phase and amplitude, can be solved using embodiments of transducers 36 of the present disclosure, by applying a voltage signal (V₂ of FIG. 4A) at the electrostatic port to control the amount of softening, and by operating the transducers 36 in transmit and receive mode, by driving with a voltage signal or by reading the electrical response, respectively, at the piezoelectric port (V₁ of FIG. 4A).

An implementation example of a phase-shift micro-beamformer 300 using one or more proposed transducers 36 of the present disclosure configuration is described in the following. In this example, an array of N=16 elements arranged in sub-arrays of elements 302 of M=4 elements, is considered. Each element 302, represented by a rectangle in

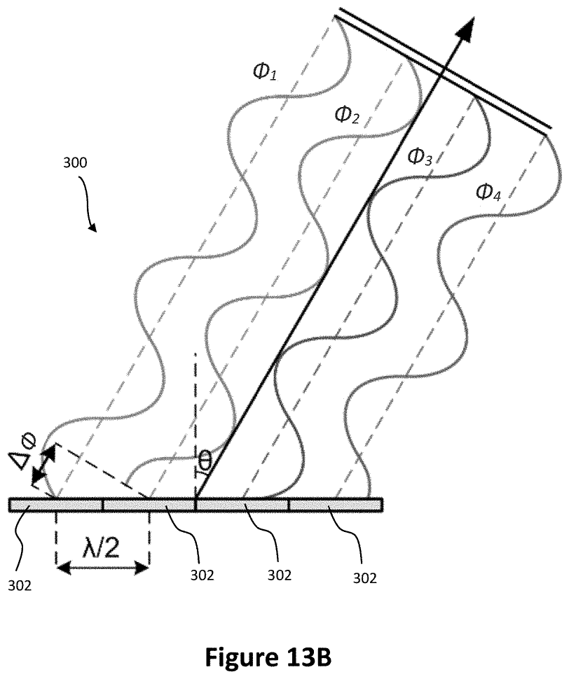

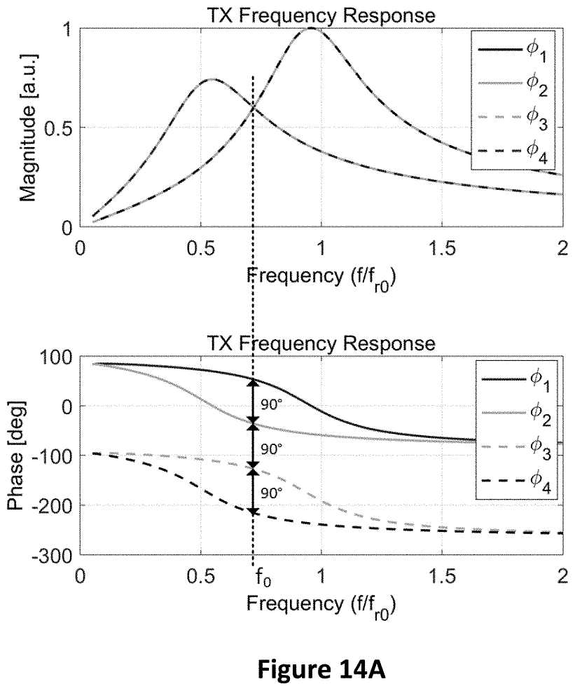

FIGS. 13A and 13B, may be composed of one or more cells of FIG. 1 connected in parallel. The pitch (i.e., the distance between the center of two adjacent elements) of the elements 302 is, for example, equal to a half wavelength (λ/2) (see FIG. 13B) at the operation frequency f₀, considering that the array is coupled to a propagation medium with a speed of sound c (λ=c/f₀).

The four piezoelectric ports of the elements 302, shown in FIG. 13A, are connected to the same system channel TX/RX, which can drive the element in transmission and read the electrical signal in reception. The four electrostatic ports are connected to four individual control signals, V_{b1}, V_{b2}, V_{b3}, and V_{b4}, which are used to bias the respective capacitive sections in order to control the phase response of the transducers 36. The control signals V_{b1}, V_{b2}, V_{b3}, and V_{b4} may readily be seen in FIG. 13A. If the transducers 36 are designed to exhibit a broadband response when coupled to the propagation medium, the variation of the bias voltage can be used to modify the phase of the frequency response, for example, for a transducer designed for a one-way, −3 dB fractional bandwidth of 50%, a variation of 90° of the phase response can be achieved by varying the bias voltage from 50% to 98% of the pull-in voltage (Vₚᵢ). Moreover, a 180° phase shift can be achieved by inverting the sign of the bias voltage. Therefore, by applying bias voltages equal to V_{b1}=0.5 Vₚᵢ, V_{b2}=0.98 Vₚᵢ, V_{b3}=−0.5 Vₚᵢ, and V_{b4}=−0.98 Vₚᵢ, a 90° phase delay between adjacent elements can be achieved. The phases of the adjacent elements 302 may be represented by Φ₁, Φ₂, Φ₃, Φ₄ as shown in FIG. 13B. In such a biasing configuration, the sub-arrays of elements 302 will emit a wavefront steered by θ=30° with respect to the direction orthogonal to the array of elements 302.

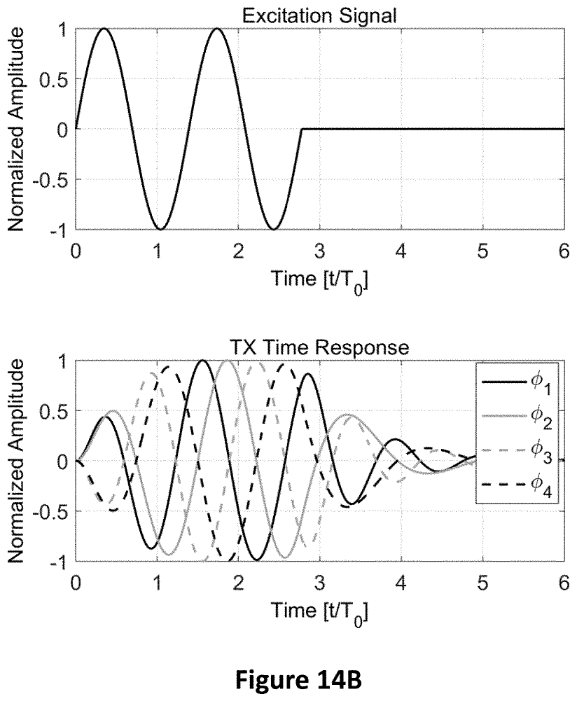

FIG. 14A shows the magnitude and phase of the complex frequency response of the four array elements, where, for a frequency f₀, the magnitude of the four array elements is the same, while the phase is delayed by 90°. FIG. 14B shows the time-domain responses of the four sub-array elements excited simultaneously with the same broadband excitation pulse, consisting of a 2-cycle sinusoidal burst centered at f₀=1/T₀. The four time-domain signals are shifted by 90°.

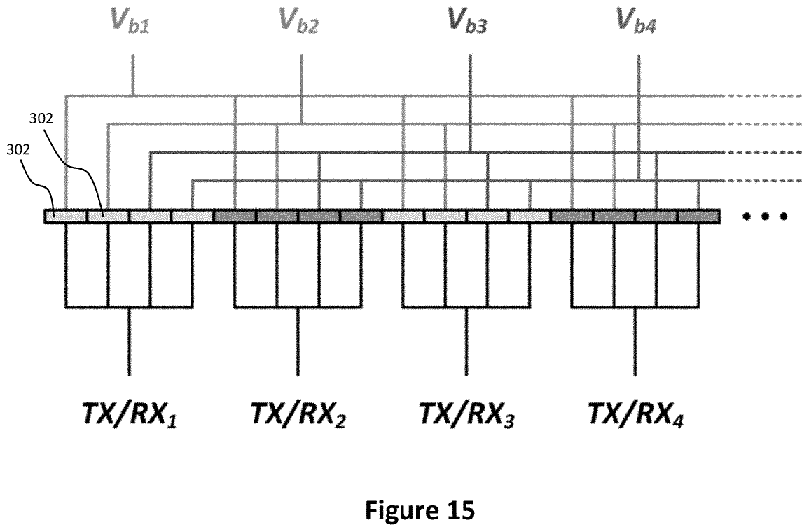

Following the described approach, several elements 302 (N/M in this example) can be combined in a larger array of N=16 elements, as shown in FIG. 15, where the TX/RX signals are reduced from N to N/M. In the example of FIG. 15, a further simplification is achieved by using the same control signals for all the elements 302, reducing the number of control signals from N to M.

A micromechanical device (20) for the transduction of acoustic waves (34) in a propagation medium, may be summarized as including a body (22); a first electrode structure (24; 32a) superimposed to the body (22) and electrically insulated from the body (22), the first electrode structure (24; 32a) and the body (22) defining between them a first buried cavity (27); and a first piezoelectric element (28) superimposed to the first electrode structure (24; 32a), wherein the body (22), the first electrode structure (24; 32a) and the buried cavity (27) form a first capacitive ultrasonic transducer (30); and the first electrode structure (24; 32a) and the first piezoelectric element (28) form a first piezoelectric ultrasonic transducer (36).

The first electrode structure (24; 32a) may include a first membrane (24) of semiconductor material and a first conductive layer (32a) extending between the first membrane (24) and the first piezoelectric element (28), the first membrane (24) forming a first terminal for the first capacitive ultrasonic transducer (30) and the first conductive layer (32a) forming a second terminal for the first piezoelectric ultrasonic transducer (36).

The micromechanical device (20) may further include a second conductive layer h(32b), superimposed to the first piezoelectric element (28), the first conductive layer (32a) and the second conductive layer (32b) being in electrical contact with the first piezoelectric element (28).

The body (22) may include a substrate (23) and a first conductive layer (30a) interposed between the substrate (23) and the first buried cavity (27),

wherein the first membrane (24), of semiconductor material, may include a membrane body (25) and a second conductive layer (30b) interposed between the substrate (23) and the first buried cavity (27), and

wherein the first conductive layer (30a) and the second conductive layer (30b) form, with the first buried cavity (27), a first capacitor (30).

The body (22) may have a first surface (22a) of its own facing the first buried cavity (27) and formed by the first conductive layer (30a), and

wherein the first membrane (24) may have a first surface (24a) of its own facing the first buried cavity (27) and formed by the second conductive layer (30b).

The body (22) may further include a first insulating layer (38a) superimposed to the first conductive layer (30a) and facing the first buried cavity (27) and/or wherein the first membrane (24) may further include a second insulating layer (38b) set underneath the second conductive layer (30b) and facing the first buried cavity (27).

The first conductive layer (30a) and the second conductive layer (30b) may be electrically connected to a tuning circuit and to a biasing circuit (170).

The tuning circuit may include a tuning impedance (Z_{c}).

The tuning impedance (Z_{c}) may include one of the following: a short circuit; an open circuit; a resistor (R) and a first capacitor (Cₑ) in parallel to one another; a first inductor (L) and a second capacitor (Cₑ) in parallel to one another; a plurality of capacitors (C, Cₑ) in parallel to one another; and a negative-impedance circuit.

The tuning circuit may include an active network or a passive network.

The first conductive layer (32a) and the second conductive layer (32b) may be configured to receive a first voltage (V₁) for actuating the first piezoelectric element (28), and the biasing circuit (170) may be configured to generate a second voltage (V₃) for governing the first capacitor (30).

The first conductive layer (32a) and the second conductive layer (32b) may be configured to generate a first voltage (V₁), and/or the first conductive layer (30a) and the second conductive layer (30b) may be configured to generate a second voltage (V₂), the first voltage (V₁) and/or the second voltage (V₂) being indicative of a vibration of the first membrane (24) induced by said acoustic waves (34) coming from the propagation medium and incident on the first membrane (24).

The micromechanical device (20) may further include at least one spacer element (26) extending between the body (22) and the first membrane (24) and laterally delimiting the first buried cavity (27).

The micromechanical device (20) may further include at least one second electrode structure (24; 32a) superimposed to the body (22) and electrically insulated from the body (22), the second electrode structure (24; 32a) defining with the body (22) a respective second buried cavity (27) pneumatically isolated from the first buried cavity (27); and a second piezoelectric element (28) superimposed to the second electrode structure (24; 32a),

wherein the body (22), the second electrode structure (24; 32a), and the second buried cavity (27) form a second capacitive ultrasonic transducer (30), and

wherein the second electrode structure (24; 32a) and the second piezoelectric element (28) form a second piezoelectric ultrasonic transducer (36).

The micromechanical device (20) may further include a membrane (24) of insulating material facing the first buried cavity (27), wherein the first electrode structure (24; 32a) may include a first conductive layer (32a) of conductive material extending over the membrane (24) and arranged between the membrane (24) and the first piezoelectric element (28), the first conductive layer (32a) forming a common terminal for the first capacitive ultrasonic transducer (30) and for the first piezoelectric ultrasonic transducer (36).

A method for manufacturing a micromechanical device (20) for transducing acoustic waves (34) in a propagation medium, may be summarized as including the steps of forming, on a body (22), a first electrode structure (24; 32a) electrically insulated from the body (22), the first electrode structure (24; 32a) and the body (22) defining between them a first buried cavity (27); and forming a first piezoelectric element (28) on the first electrode structure (24; 32a); the body (22), the first electrode structure (24; 32a) and the buried cavity (27) forming a capacitive ultrasonic transducer (30); and the first electrode structure (24; 32a) and the first piezoelectric element (28) forming a piezoelectric ultrasonic transducer (36).

The body (22) may include a substrate (23) and a first conductive layer (30a) facing the first buried cavity (27).

The step of forming the first electrode structure (24; 32a) may include forming, on a membrane body (25), a second conductive layer (30b) facing the first buried cavity (27).

The step of forming the first electrode structure (24; 32a) may include bonding together the body (22) and the first electrode structure (24; 32a) through interposition of one or more spacer elements (26), the one or more spacer elements (26) spacing the body (22) and the first electrode structure (24; 32a) from one another and delimiting the first buried cavity (27).

The step of forming the first electrode structure (24; 32a) may include forming a sacrificial layer (75) on a first surface (22a) of the body (22), at a first region (76) of the first surface (22a) of the body (22); forming a spacer element (26) on the first surface (22a) of the body (22), at a second region (77) of the first surface (22a) of the body (22) contiguous to the first region (76); and after forming the first electrode structure (24; 32a) on the spacer element (22a) and on the sacrificial layer (75), removing the sacrificial layer (75) through etching to form the first buried cavity (27) at the first region (76).

A system may be summarized as including a plurality of transducers, each one of the plurality of transducers including a capacitive ultrasonic transducer configured to receive or be controlled by a first voltage and configured to generate a spring-softening effect in response to the first voltage, and a piezoelectric ultrasonic transducer on and coupled to the capacitive ultrasonic transducer, the first piezoelectric transducer is configured to or be controlled by a second voltage different from the first voltage, the first and second voltages are configured to control a phase and amplitude of an electro-acoustic response. The first voltage may be a bias voltage and the second voltage may be an excitation or drive voltage. The second voltage may be configured to vibrate the piezo-electric transducer to generate acoustic waves and control the amplitude. The first voltage may be configured to control the phase.

The first voltage may be constant. Alternatively, the first voltage may vary slowly with respect to the excitation voltage during a transmit and receive time interval.

The capacitive ultrasonic transducer may be configured to be controlled by a third voltage, such as a constant bias voltage, and be loaded with an externally controlled variable electrical impedance, consequently controlling the phase of the electro-acoustic response.

The plurality of transducers may be configured to perform phase-delay beamforming including beam focusing and steering in response to the spring-softening effect of the capacitive ultrasonic transducers.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A micromechanical device, comprising:
a body;
at least one spacer element coupled to the body;
a first electrode structure coupled to the at least one spacer element, the first electrode structure superimposed to the body and overlapping the body, the first electrode structure electrically insulated from the body, and the first electrode structure, the body, and the at least one spacer element delimiting a first buried cavity having a first dimension extending between opposite ones of respective sidewalls of ones of the at least one spacer element; and
a first piezoelectric element coupled to the first electrode structure, the first piezoelectric element superimposed to and overlapping the first electrode structure, the first piezoelectric element overlapping the first buried cavity, the first piezoelectric element having a second dimension extending between opposite ones of respective sidewalls of the first piezoelectric element, the second dimension being less than the first dimension of the first buried cavity,
wherein the body, the first electrode structure and the buried cavity form a first capacitive ultrasonic transducer, and
the first electrode structure and the first piezoelectric element form a first piezoelectric ultrasonic transducer.

2. The micromechanical device according to claim 1, wherein the first electrode structure comprises a first membrane of semiconductor material and a first conductive layer extending between the first membrane and the first piezoelectric element, the first membrane forming a first terminal for the first capacitive ultrasonic transducer and the first conductive layer forming a second terminal for the first piezoelectric ultrasonic transducer.

3. The micromechanical device according to claim 2, further comprising a second conductive layer, superimposed to the first piezoelectric element, the first conductive layer and the second conductive layer being in electrical contact with the first piezoelectric element.

4. The micromechanical device according to claim 2, wherein the body comprises a substrate and a first conductive layer interposed between the substrate and the first buried cavity,
wherein the first membrane, of semiconductor material, comprises a membrane body and a second conductive layer interposed between the first buried cavity and the piezoelectric element, and
wherein the first conductive layer and the second conductive layer form, with the first buried cavity, a first capacitor, and
wherein the first conductive layer and the second conductive layer are spaced apart from each other by the first buried cavity and delimit the first buried cavity along with the at least one spacer.

5. The micromechanical device according to claim 4, wherein the body has a first surface of the first conductive layer facing the first buried cavity , and
wherein the first membrane has a first surface of the second conductive layer facing the first buried cavity.

6. The micromechanical device according to claim 4, wherein:
the body further comprises a first insulating layer superimposed to the first conductive layer, the first insulating layer is between the first conductive layer and the first buried cavity; and
the first membrane further comprises a second insulating layer superimposed to the second conductive layer, the second insulating layer is between the first buried cavity and the second conductive layer.

7. The micromechanical device according to claim 4, wherein the first conductive layer and the second conductive layer are electrically connected to a tuning circuit and to a biasing circuit.

8. The micromechanical device according to claim 7, wherein the tuning circuit comprises a tuning impedance.

9. The micromechanical device according to claim 8, wherein the tuning impedance comprises at least one of the following: a short circuit, an open circuit, a resistor and a first capacitor in parallel to one another, a first inductor and a second capacitor in parallel to one another, a plurality of capacitors in parallel to one another, and a negative-impedance circuit.

10. The micromechanical device according to claim 7, wherein the tuning circuit comprises an active network or a passive network.

11. The micromechanical device according to claim 7, wherein:
the first conductive layer and the second conductive layer are configured to receive a first voltage for actuating the first piezoelectric element; and
the biasing circuit is configured to generate a second voltage for governing the first capacitor.

12. The micromechanical device according to claim 4, wherein:
the first conductive layer and the second conductive layer are configured to generate a first voltage; and
the first conductive layer and the second conductive layer are configured to generate a second voltage, the first voltage, the second voltage being indicative of a vibration of the first membrane induced by the acoustic waves coming from the propagation medium and incident on the first membrane.

13. The micromechanical device according to claim 1, wherein the at least one spacer element extending between the body and the first membrane and laterally delimiting the first buried cavity.

14. The micromechanical device according to claim 1, further comprising a membrane of insulating material facing the first buried cavity, wherein the first electrode structure comprises a first conductive layer of conductive material extending over the membrane and arranged between the membrane and the first piezoelectric element, the first conductive layer forming a common terminal for the first capacitive ultrasonic transducer and for the first piezoelectric ultrasonic transducer.

15. A method, comprising:
forming a capacitive ultrasonic transducer including:
coupling a first electrode structure to a body with at least one spacer element insulating the first electrode structure from the body, coupling the first electrode structure to the body including:
forming a buried cavity with the first electrode structure , the body, and the at least one spacer element, coupling the first electrode structure to the body with the at least one spacer element defining a first dimension of the buried cavity extending between opposite ones of respective sidewalls of the at least one spacer element;
forming a piezoelectric ultrasonic transducer including:
forming a first piezoelectric element on the first electrode structure, forming the first piezoelectric element including:
defining a second dimension of the first piezoelectric element extending between opposite ones of respective sidewalls of the first piezoelectric element, the second dimension being less than the first dimension.

16. The manufacturing method according to claim 15, wherein coupling the first electrode structure to the body comprises:
forming a sacrificial layer on a first surface of the body and at a first region of the first surface of the body;
forming the at least one spacer element on the first surface of the body, at a second region of the first surface of the body adjacent to the first region; and
forming the first electrode structure to the at least one spacer element and to the sacrificial layer; and
removing the sacrificial layer through etching to form the first buried cavity at the first region.

17. The manufacturing method according to claim 15, further comprising:
forming a sacrificial layer on a first surface of a first layer of the body present on a substrate of the body;
forming at least one spacer on respective sidewalls of the sacrificial layer; and
forming a conductive layer on a surface of the piezoelectric element facing away from the buried cavity.

18. A micromechanical device, comprising:
a substrate;
a first conductive layer on the substrate, the first layer having a first surface facing away from the substrate;
at least one spacer element on the first surface of the first layer, the at least one spacer including a first sidewall and a second sidewall opposite to the first sidewall;
a second conductive layer on the at least one spacer element, the second conductive layer having a second surface facing towards the substrate;
a buried cavity delimited by the first surface, the first sidewall, the second sidewall, and the second surface, the buried cavity having a first dimension extending from the first sidewall to the second sidewall;
a membrane body on the second layer;
a third conductive layer on the membrane body;
a piezoelectric element on the first conductive layer having a third sidewall and a fourth sidewall opposite the third sidewall, the piezoelectric element having a second dimension extending from the third sidewall to the fourth sidewall, the second dimension is less than the first dimension; and
a fourth conductive layer on the piezoelectric element.

19. The device of claim 18, further comprising:
a capacitive ultrasonic transducer including the first conductive layer and the second conductive layer; and
a piezoelectric ultrasonic transducer including the second conductive layer and the third conductive layer.

20. A system, comprising:
a plurality of transducers, each one of the plurality of transducers including:
a capacitive ultrasonic transducer configured to be controlled by a first voltage and configured to generate a spring-softening effect in response to the first voltage, the first voltage configured to control a phase of an electro-acoustic response; and
a piezoelectric ultrasonic transducer on and coupled to the capacitive ultrasonic transducer, the first piezoelectric transducer is configured to be controlled by a second voltage different from the first voltage, the second voltage configured to control an amplitude of the electro-acoustic response.

21. The system of claim 20, wherein the first voltage is constant.

22. The system of claim 20, wherein the capacitive ultrasonic transducer configured to be controlled by a third voltage and be loaded with an externally controlled variable electrical impedance to control the phase of the electro-acoustic response.

23. The system of claim 20, wherein the plurality of transducers are configured to perform phase-delay beamforming including beam focusing and steering in response to the spring-softening effect of the capacitive ultrasonic transducers.
